(19) United States
(12) Patent Application Publication
(10) Pub. No.: US 2013/0122712 A1
(43) Pub. Date: May 16, 2013

(54) METHOD OF ETCHING HIGH ASPECT RATIO FEATURES IN A DIELECTRIC LAYER

(71) Applicants: Jong Mun KIM, San Jose, CA (US); Kenny Linh Doan, San Jose, CA (US); Li Ling, San Jose, CA (US); Jairaj Payyapilly, Sunnyvale, CA (US); Daisuke Shimuzu, Sunnyvale, CA (US); Srinivas D. Nemani, Sunnyvale, CA (US); Thorsten B. Lill, Santa Clara, CA (US)

(72) Inventors: Jong Mun KIM, San Jose, CA (US); Kenny Linh Doan, San Jose, CA (US); Li Ling, San Jose, CA (US); Jairaj Payyapilly, Sunnyvale, CA (US); Daisuke Shimuzu, Sunnyvale, CA (US); Srinivas D. Nemani, Sunnyvale, CA (US); Thorsten B. Lill, Santa Clara, CA (US)

(21) Appl. No.: 13/656,578

(22) Filed: Oct. 19, 2012

Related U.S. Application Data
(60) Provisional application No. 61/559,617, filed on Nov. 14, 2011.

(51) Int. Cl. H01L 21/3065

(52) U.S. Cl. 438/714; 257/E21.218

(57) ABSTRACT

Methods of etching HAR features in a dielectric layer are described. In one embodiment, a substrate is provided into an etch chamber. The substrate has a patterned mask disposed on a dielectric layer formed thereon where the patterned mask has openings. A gas mixture is provided into the etch chamber, the gas mixture includes CO, O₂, a fluorocarbon gas, and an optional inert gas. A plasma is formed from the gas mixture. Features are etched in the dielectric layer through the openings in the presence of the plasma

### CROSS-REFERENCE TO RELATED APPLICATIONS

This application claims the benefit of and priority to U.S. Provisional Application No. 61/559,617, filed Nov. 14, 2011, the entire contents of which are hereby incorporated by reference herein.

### BACKGROUND

1) Field

This invention relates to a method of etching high aspect ratio features in a dielectric layer.

2) Description of Related Art

High aspect ratio (HAR) etching of features such as contacts holes and trenches in dielectric layers is a key process in integrated circuit (IC) fabrication. For example, etching high aspect ratio contacts (HARC) through dielectric layers is important in the formation of electrical interconnections between different conductive layers. In dynamic random access memory (DRAM) fabrication, HAR container structures are etched through dielectrics layers in the formation of stacked capacitors. In 3D vertical NAND application, etching HAR contacts and trenches in dielectric layers are also important in the fabrication of the vertical channels and word line structures.

As IC manufacturers strive to achieve greater circuit density and higher performance, modern integrated circuits are scaled with increasingly narrower design rules. The widths of etched features decrease with scaling while the corresponding aspect ratios increase, thereby presenting greater challenges for the HAR etch process. One of the major challenges in HAR etching is polymer management. Smaller width features with higher aspect ratios are more susceptible to the effects of polymer build-up during etching. Polymer build-up on the etch front and polymer clogging at the top of the openings results in problems such bowing of the etch feature profile, bottom critical dimension (CD) distortion, etch stop, etch delay, and low etch rates. FIG. 1 through FIG. 3B show HAR contact holes formed by convention etch methods in a layer stack 10 having a mask 12, a dielectric layer 14, and a substrate 16. FIG. 1 illustrates etched HAR contacts holes 104 having bowing 106 sidewall profiles. The accumulation of polymer 102 at the top of the openings 108 along with charge build-up on the sidewalls of the openings during etching increases ion deflection and bending. As a result, the sidewalls of the HAR contacts holes 104 are laterally attacked by etchant ion species during etching, creating the bowing characteristic 106. FIG. 2 illustrates excessive polymer build-up in the openings 212, 212′ during the etching of contact holes 204, 204′, resulting in polymer necking 202 and polymer clogging 202′. The polymer necking 202 narrows the opening 212 and causes bottom hole distortion where the bottom CD 208 becomes significantly smaller than the top CD 206. Polymer clogging 202′ blocks the supply of etchant species to the etch front, thereby causing ‘etch stop’ where the bottom of the contact hole 210 stops short of the target depth. Polymer necking and polymer clogging at the top opening also causes lower etch rates due to fewer etchant species reaching the bottom of the contact hole.

Conventional methods of etching HAR features in a dielectric layer utilize oxygen (O₂) gas for polymer management. However, providing concentrations of O₂ that are too high may result in poor mask selectivity and distortion in the mask openings. During etching, O₂ neutrals and O₂⁺ ions are formed from the O₂ in plasma. The O₂ neutrals may erode the mask and reduce mask etch selectivity while the O₂⁺ ions may laterally attack the mask openings and distort the top CDs and profiles of the openings. FIG. 3A shows distortion in the mask openings 304 caused by O₂ neutrals and O₂+ ions eroding and attacking the mask 12 during the etching of HAR contact holes 302. As the etch progresses, the distorted mask openings 304 result in the formation of contact holes 302 having significantly larger top CDs 306 than intended. Forming distorted HAR contacts such as those shown in FIG. 1 to FIG. 3B may cause device failure and reliability issues.

Thus, a method etching high aspect ratio features in a dielectric layer is described herein.

### SUMMARY

Embodiments of the present invention include methods of etching HAR features in a dielectric layer. In one embodiment, the method includes providing a substrate into an etch chamber. The substrate has a patterned mask disposed on a dielectric layer formed thereon. The patterned mask has openings. A gas mixture is provided into the etch chamber. The gas mixture includes CO, O₂, a fluorocarbon gas, and an inert gas. A plasma is formed from the gas mixture. Features are etched in the dielectric layer through the openings in the presence of the plasma.

### BRIEF DESCRIPTION OF THE DRAWINGS

Embodiments of the present disclosure is illustrated by way of example, and not by way of limitation, in the figures of the accompanying drawings, in which:

FIG. 1 illustrates HAR contact holes with bowing sidewall profiles formed using conventional etch methods.

FIG. 2 illustrates HAR contact holes with necking, clogging, bottom hole distortion, and etch stop formed using conventional etch methods.

FIG. 3A and 3B illustrate HAR contact holes with distorted mask openings and large top CDs formed using conventional etch methods.

FIG. 4 is a flowchart representing operations in a method of etching HAR features in a dielectric layer, in accordance with an embodiment of the present invention.

FIGS. 5A and 5B illustrate the cross-sectional views representing various operations in a method of etching HAR features in a dielectric layer, in accordance with various embodiments of the present invention.

FIGS. 6A and 6B illustrate the cross-sectional views of a substrate having a patterned mask disposed on a dielectric layer formed thereon, in accordance with an embodiment of the present invention.

FIG. 7 illustrates an exemplary system in which a method of etching HAR features in a dielectric layer may be performed, in accordance with an embodiment of the present invention.

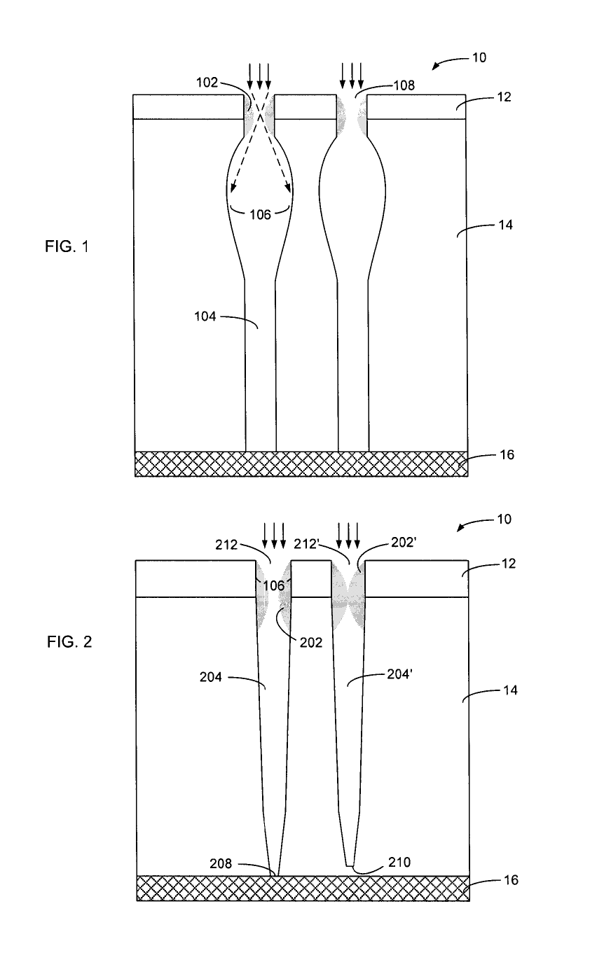

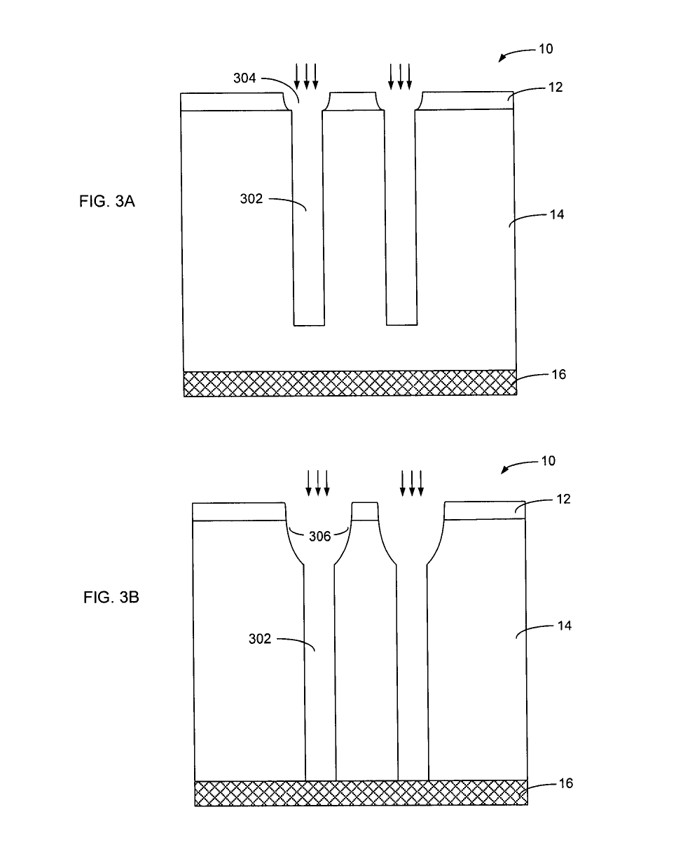

### DETAILED DESCRIPTION

Methods of etching high aspect ratio (HAR) features in a dielectric layer are described. In the context of the current application, the term “high aspect ratio” (HAR) features refers to features with depth to width ratios of about 20:1 or more. In the following description, numerous details are set forth. It will be apparent, however, to one skilled in the art, that the present invention may be practiced without these specific details. In other instances, well-known aspects, such as photolithography patterning and development for mask formation, are not described in detail to avoid obscuring the present invention. Reference throughout this specification to “an embodiment” means that a particular feature, structure, function, or characteristic described in connection with the embodiment is included in at least one embodiment of the invention. Thus, the appearances of the phrase “in an embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the two embodiments are not mutually exclusive.

During etching of HAR features in dielectrics, polymer build-up at the etch front or in the mask openings may cause problems such as low etch rates, etch stop, and distortions in the sidewall profiles, top CDs, and bottom CDs of the HAR features. A HAR etch process with good polymer management is therefore key in achieving HAR features in dielectric layers with roughly straight sidewall profiles and targeted top and bottom CDs. At the same time the HAR etch process must maintain high mask etch selectivity to minimize the mask thickness required for the process and to preserve the top CDs and profiles of the mask openings during etching. The mask etch selectivity with respect to dielectric etch is the ratio of the dielectric etch rate to the mask etch rate.

In accordance with one or more embodiments of the present invention, a HAR dielectric etch method using a gas mixture that includes carbon monoxide (CO), oxygen (O₂), a fluorocarbon gas, and an inert gas is disclosed. In one such embodiment, the gas mixture contains a significantly greater proportion of CO compared to O₂. The CO dissociates during etching to form a carbon species and an oxygen species. The carbon species reinforces the mask during etching and maintains high mask etch selectivity. The oxygen species removes polymer build-up at the bottom and sidewalls of the openings during etching to prevent polymer necking, polymer clogging, and etch stop. The CO gas also moderates the negative effects of O₂ gas on the mask by acting as a diluent, thereby reducing the erosion and distortion of the mask openings caused by O₂ neutrals and O₂⁺ ions during etching.

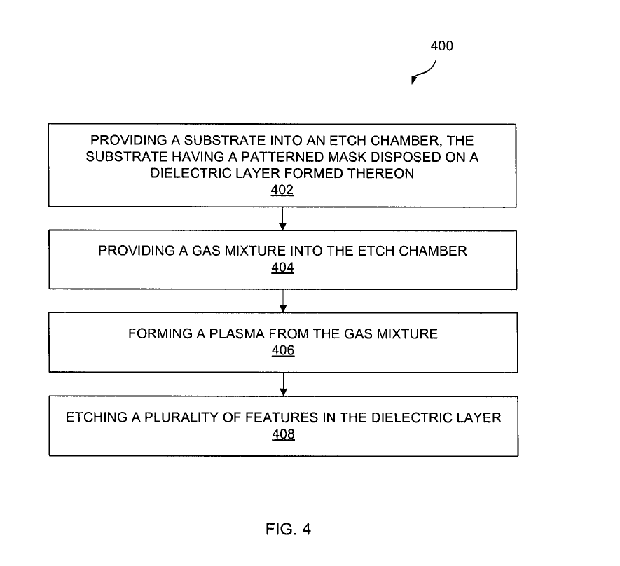

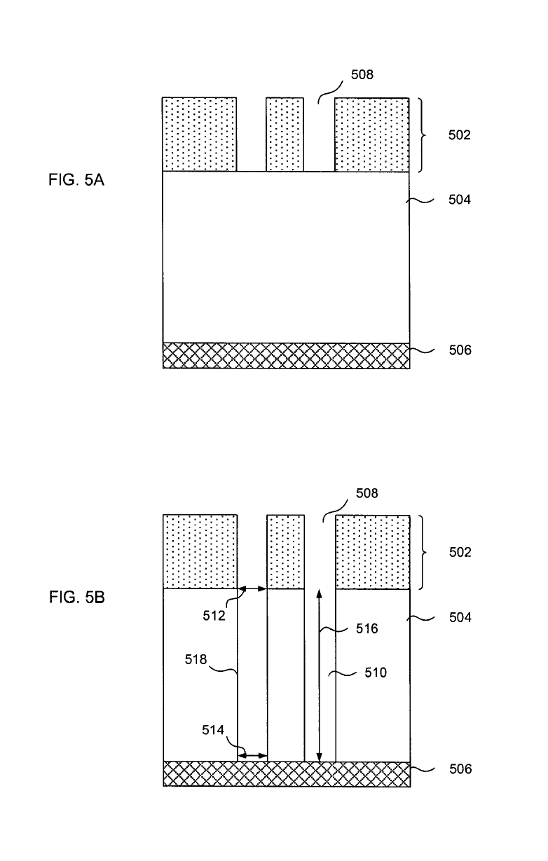

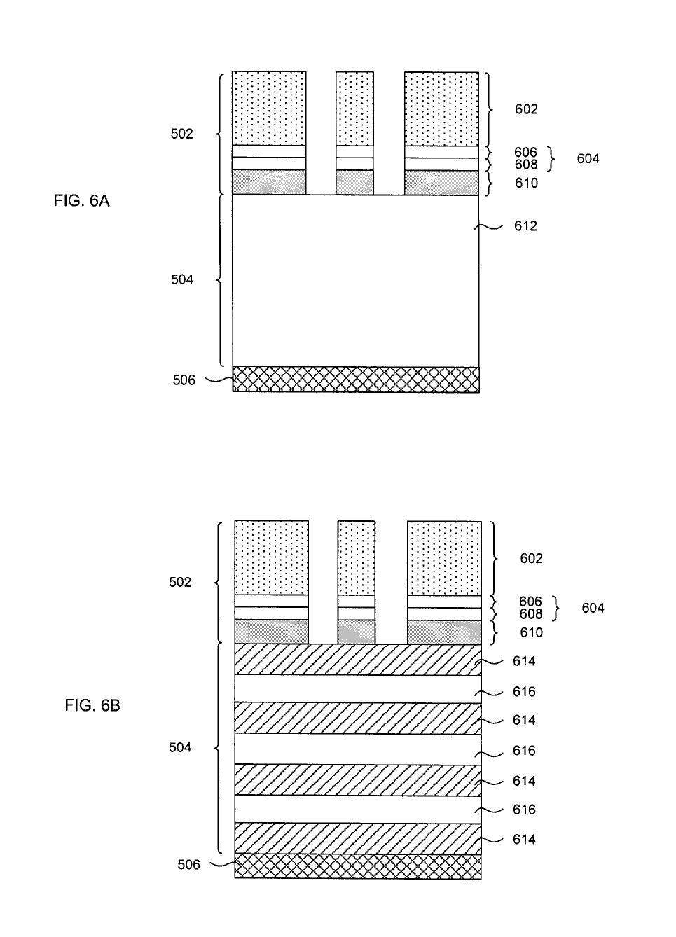

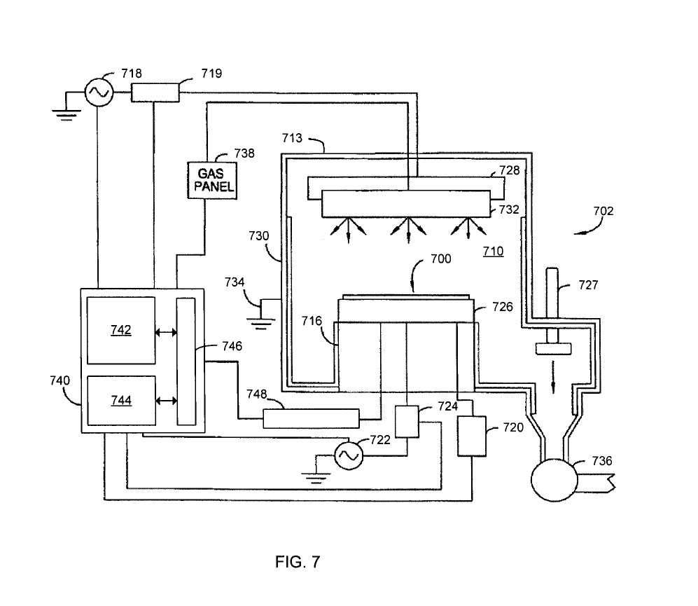

FIG. 4 is a flowchart 400 of one embodiment of a method of etching HAR features in a dielectric layer. FIGS. 5A and 5B illustrate cross-sectional views representing a method of etching HAR features in a dielectric layer. The method begins at operation 402 by providing a substrate into an etch chamber. An example of a suitable etch chamber 710 is illustrated in FIG. 7 and is described later in greater detail. Referring to FIG. 5A, the substrate 506 has a patterned mask 502 disposed on a dielectric layer 504 formed thereon. The patterned mask 502 has openings 508, such as, but not limited to holes or trenches, and may comprise of any material that is resistant to dielectric plasma etching. In one embodiment, the patterned mask may include a photoresist layer patterned via a lithography or direct-write process. In another embodiment, the patterned mask may include a patterned hard mask layer, such as a hard mask layer selected from the group consisting of silicon dioxide (SiO₂), silicon oxynitride (SiON), silicon nitride (SiN), silicon carbide (SiC), silicon nitride carbide (SiCN), amorphous silicon (α-Si), amorphous carbon (α-carbon), and a metal film. One example of a α-carbon layer is the Advanced Patterning Film™ (APF) available from Applied Materials, Inc. of Santa Clara, Calif. In another embodiment, the patterned mask 502 may comprise of a photoresist layer 602, an anti-reflective coating (ARC) layer 604 and a α-carbon hard mask layer 610, as shown in FIGS. 6A and 6B. The ARC layer 604 may include a bottom anti-reflective coating (BARC) layer 606 and a dielectric anti-reflective coating (DARC) layer 608.

Referring to FIG. 5A, the dielectric layer 504 may comprise of any dielectric material suitable for fabricating HAR features such as, but not limited to contact holes and trenches, that are necessary in the fabrication of integrated circuits or microelectromechanical systems (MEMS). In one embodiment, the dielectric layer comprises of a dielectric layer selected from the group consisting of SiO₂, SiON, SiN, SiC, SiCN, SiOC, and a low-k dielectric. In another embodiment, the dielectric layer may be a composite layer including at least two layers selected from the materials described above. In a particular embodiment, the dielectric layer 504 may comprise of a silicon dioxide layer 612 with a thickness between about 1 and 3 microns as shown in FIG. 6A. The dielectric oxide layer may be an undoped silicon oxide or a doped silicon oxide (e.g., BSG, PSG, and BPSG). In another embodiment shown in FIG. 6B, the dielectric layer 504 may comprise of multiple alternating layers of silicon nitride 614 and silicon dioxide 616 with a total thickness of at least 3 microns.

Referring to FIG. 5A, the substrate 506 may comprise of any one of semiconductor bulk substrates such as crystalline silicon or germanium. In one embodiment, the substrate 506 includes a bulk substrate that is comprised of a group III-V material such as, but not limited to, gallium nitride, gallium phosphide, gallium arsenide, indium phosphide, indium antimonide, indium gallium arsenide, aluminum gallium arsenide, indium gallium phosphide or a combination thereof In another embodiment, the substrate 506 is a glass bulk substrate. In an alternative embodiment, the substrate 506 comprising of an epitaxial layer grown atop a distinct crystalline substrate, e.g. a silicon epitaxial layer grown atop a boron-doped bulk silicon mono-crystalline substrate. Substrate 506 may also comprise an insulating layer (e.g., silicon dioxide, silicon nitride, silicon oxynitride and a high-k dielectric layer) in between a bulk crystal substrate and an epitaxial layer to form, for example, a silicon-on-insulator substrate. In one embodiment, the substrate 506 may include other layers or structures such as field effect transistors, MEMS, electrical interconnects, insulating layers, and conductive wires formed on any one of the bulk substrates described above.

At operation 404 in flowchart 400, a gas mixture is provided into the etch chamber. The gas mixture includes CO, O₂, a fluorocarbon gas, and an optional inert gas. In one embodiment, the gas mixture is provided into the etch chamber at a flow rate between about 200 sccm and 1500 sccm. The fluorocarbon gas may be a compound having a general formula CₓH_{y}F_{z}, where x=1-6, y=0-6, and z=2-10, such as, but not limited to C₄F₆, C₄F₈, C₂F₄, C₂F₆, C₃F₆, C₅F₈, CF₄, C₆F₆, CH₃F, CH₂F₂, and CHF₃. In one embodiment, the fluorocarbon gas may comprise of two or more compounds described above. In a particular embodiment, the fluorocarbon gas is selected from the group consisting of C₄F₆ and C₄F₈. The fluorocarbon gas is provided into the etch chamber at a flow rate between about 10 sccm and 150 sccm. The gas mixture includes an inert gas only when the dielectric layer includes a silicon dioxide layer. The inert gas may be selected from the group consisting of argon, helium, neon, krypton, and xenon. In a specific embodiment, the inert gas is argon. The inert gas is provided into the etch chamber at a flow rate between about 0 sccm and 800 sccm. In another embodiment, the dielectric layer includes a dielectric material other than silicon dioxide (e.g. silicon nitride, silicon oxynitride) and the gas mixture includes a hydrofluorocarbon gas. The hydrofluorocarbon gas is a compound having a general formula CₓH_{y}F_{z}, where x=1-6, y=1-6, and z=0-10, such as, but not limited to CH₄, CH₃F, CH₂F₂, CHF₃, C₃H₃F₃, and C₂H₂F₆. In a specific embodiment, the dielectric layer includes a silicon nitride layer and the gas mixture includes the hydroflurocarbon gas CH₂F₂.

The CO and O₂ gases are important for managing polymer growth while maintaining high mask etch selectivity during HAR etching. The O₂ gas is aggressive in removing polymer build-up in the openings and prevents polymer necking, polymer clogging, and etch stop. However, high concentrations of O₂ in the etch chamber may cause significant erosion of the patterned mask, thereby resulting in distorted openings. In one embodiment, the O₂ is provided into the etch chamber at a flow rate sufficient to provide good polymer management without excessively eroding the patterned mask. In one such embodiment, the O₂ is provided into the etch chamber at a flow rate between about 10 sccm and 80 sccm. The CO functions as a diluent for the O₂ and moderates the erosive effects of the O₂ on the patterned mask. In addition, the CO removes polymer build-up in the openings during etching and reinforces the mask, thereby improving mask etch selectivity. In one embodiment, the CO flow rate is sufficient to maintain a high mask etch selectivity and prevent polymer necking and polymer clogging of the openings. The CO flow rate may be between about 10% and 50% of the gas mixture flow rate. In an embodiment, the CO flow rate is between about 10 sccm and 1000 sccm. In a particular embodiment, the CO flow rate is between about 50 sccm and 400 sccm. The CO flow rate may be constant throughout the etch process. Alternatively, the CO flow rate may be ramped up during the etch process. In an embodiment, the CO flow rate is ramped up from about 10% of the gas mixture flow rate to a maximum of 50% of the gas mixture flow rate during the etch process.

Regulating the flow rate ratio of CO to O₂ during the etch process prevents excessive erosion of the patterned mask while providing sufficient polymer management. In an embodiment, the flow rate ratio of CO to O₂ into the etch chamber is between about 1:1 and 10:1. In another embodiment, the flow rate ratio of CO to O₂ into the etch chamber is between about 3:1 and 6:1. In a specific embodiment, the flow rate ratio of CO to O₂ into the etch chamber is about 5:1.

Referring to operation 406 in flowchart 400, a plasma is formed from the gas mixture. The plasma may be formed by supplying one or more power sources to the etch chamber. In one embodiment, a radio frequency (RF) source power supplies between about 300 W and 3,000 W of power normalized to a 300 mm substrate at a frequency between about 40 MHz and 162 MHz. In a further embodiment, a RF bias power source supplies between about 1,000 W and 8,000 W of power normalized to a 300 mm substrate to the etch chamber. The RF bias power may have a frequency between 2 MHz and 60 MHz or a mixture of one or more frequencies between 2 MHz and 60 MHz. The method may include generating a chamber pressure between about 5 mT and 200 mT.

The CO gas dissociates in the plasma to form a carbon species and an oxygen species, where the carbon species improves the etch selectivity of the patterned mask and the oxygen species removes polymer during etching, thereby preventing polymer necking and polymer clogging in the openings. The dissociation of the CO gas is dependent on the chamber pressure and the power source provided.

Referring to operation 404 in flowchart 400 and to the corresponding FIG. 5B, features 510 such as contact holes and trenches are etched in the dielectric layer 504 through the openings 508. The etching takes place in the presence of the plasma. Each feature has a top CD 512, a bottom CD 514, a depth 516, a sidewall profile 518, and an aspect ratio. The aspect ratio of a feature is the ratio of the depth 516 to the top CD 512. In one embodiment, the etched features include a feature having an aspect ratio of at least 40:1. In another embodiment, the etched features include a feature having a top CD of 50 nm or less. In a particular embodiment, the etched features include a feature with a top CD of 50 nanometers or less and an aspect ratio of at least 40:1. In one embodiment, the etched features have roughly straight sidewall profiles with no bowing, no polymer necking or polymer clogging, and no etch stop. The absence of polymer necking or polymer clogging allows more ions and neutral etchant species to reach the etch front during etching and increases the etch rate. In one embodiment, HAR contact holes are etched in a SiO₂ dielectric layer with an etch rate greater than 5500 A/min. In a further embodiment, a mask etch selectivity of at least 15 is achieved during the HAR etch process.

Methods of etching HAR features in a dielectric layer described herein may be performed in any suitably adapted plasma etch system such as the Applied Centura® Enabler etch system, available from Applied Materials of Santa Clara, Calif., USA or the Applied Centura® Producer Etch system with a twin chamber design, also available from Applied Materials of Santa Clara, Calif., USA. It is contemplated that suitably adapted plasma etch systems, including those available from other manufacturers, may also be utilized to practice the present invention.

FIG. 7 depicts a schematic, cross-sectional diagram of an exemplary plasma etch system 702 suitable to perform etching of high aspect ratio features in a dielectric layer according to embodiments of the present invention. In one embodiment, the plasma etch system 702 includes an etch chamber 710 connected to an electrical ground 734. The etch chamber 710 is a high vacuum vessel that is coupled through a throttle valve 727 to a vacuum pump 736. The etch chamber 710 includes a support pedestal 716 and a showerhead 732. The support pedestal 716 is disposed below the showerhead 732 in a spaced-apart relation. The support pedestal 716 is coupled to a radio frequency (RF) bias power source 722 through a matching network 724. The support pedestal 716 may include a chuck 726, such as an electrostatic chuck (ESC), for retaining a substrate 700 during processing. The chuck may be powered by a DC power supply 720. The temperature of the chuck 726 may be regulated during processing by heating or cooling the chuck with a heat exchanger 7148. The temperature of the substrate 700 may be partially controlled by regulating the temperature of the chuck 726.

The showerhead 732 is mounted to a lid 713 of the etch chamber 710. A gas panel 738 is fluidly coupled to a plenum (not shown) defined between the showerhead 732 and the lid 713. Processing gases are provided from the gas panel 738 to the plenum. The processing gases intermix in the plenum before entering into the etch chamber 710 as a gas mixture through a plurality of orifices in the showerhead 732. Mass flow controllers (not shown) in the gas panel 738 may regulate the volumetric flow rates of the processing gases provided from the gas panel 738 into the etch chamber 710. The showerhead 732 and/or an upper electrode 728 positioned proximate thereto may also be coupled to an RF source power 718 through an impedance transformer 719 (e.g., a quarter wavelength matching stub).

In an embodiment of the present invention, a controller 740 is coupled to various components of the plasma etch system and controls the plasma etch system to perform the processes of the present invention. The controller regulates the chamber pressure by controlling the mass flow controllers in the gas panel 738 and the throttle valve 727. The controller regulates the processing gas flow rates and the ratios of the different processing gases provided into the etch chamber by controlling the mass flow controllers in the gas panel 738. The controller sets the magnitudes and the frequencies of the RF source power and RF bias power provided into the etch chamber by controlling the RF source power 718 and RF bias power 722 sources. The controller also regulates the temperature of the chuck 726 by controlling the heat exchanger 7148.

The controller includes a processor 746 in communication with memory 742, and support circuits 750. The processor may be one or more general-purpose processing devices such as a microprocessor, a central processing unit (CPU), or the like. The memory 742 may be any computer-readable medium, such as, but not limited to random access memory (RAM), read only memory (ROM), floppy disk, hard disk, or any other form of digital storage, local or remote to the plasma etch system 702 or processor 746. The support circuits 746 are coupled to the processor 746 for supporting the processor 746 in a conventional manner. These circuits include cache, power supplies, clock circuits, input/output circuitry and subsystems, and the like. The memory 742 may include a machine-accessible storage medium such as a computer-readable storage medium on which is stored one or more sets of program instructions (e.g., software routine) embodying any one or more of the methodologies or functions of the present invention described herein. The one or more sets of program instructions stored in the memory 742, when executed by the processor 744, causes the plasma etch system 702 to perform any one or more of the methods of polymer deposition to form reduced CDs as described herein.

In accordance with an embodiment of the present invention, a machine-accessible storage medium has a set of machine executable instructions stored thereon which, when executed by a controller, cause a suitable plasma etch system to perform a method of etching HAR features in a dielectric layer as previously described herein. The method includes providing a substrate into an etch chamber. The substrate has a patterned mask disposed on a dielectric layer formed thereon where the patterned mask has openings. A gas mixture is provided into the etch chamber, the gas mixture includes CO, O2, an inert gas, and a fluorocarbon gas. A plasma is formed from the gas mixture. Features are etched in the dielectric layer through the openings in the presence of the plasma.

What is claimed is:

1. An etching method comprising:
providing a substrate into an etch chamber, said substrate having a patterned mask disposed on a dielectric layer formed thereon, wherein the patterned mask has a plurality of openings;
providing a gas mixture into the etch chamber, said gas mixture including CO, O₂, a fluorocarbon gas, and an optional inert gas;
forming a plasma from the gas mixture; and,
etching in the presence of the plasma, a plurality of features in said dielectric layer through the plurality of openings, each feature having an aspect ratio, a top critical dimension, and a sidewall profile.

2. The method of claim 1, wherein the CO and O₂ are provided at a ratio between about 1:1 and 10:1.

3. The method of claim 2, wherein the CO to O₂ are provided at a ratio between about 3:1 and 6:1.

4. The method of claim 2, wherein the CO flow rate is between about 10% and 50% of the gas mixture flow rate.

5. The method of claim 1, further comprising increasing the CO flow rate as a percentage of the gas mixture flow rate during etching.

6. The method of claim 1, wherein said fluorocarbon gas is a compound having a general formula CₓH_{y}F_{z} where x=1-6, y=0-6, and z=2-10.

7. The method of claim 1, further comprising generating a chamber pressure between about 5 mT and 200 mT during etching.

8. The method of claim 1, further comprising providing to the etch chamber between about 1,000 and 10,000 W of power normalized to a 300 mm substrate from one or more power sources.

9. The method of claim 8, wherein said power source includes a RF power source generating power at a frequency between 2 MHz and 500 MHz.

10. The method of claim 1, wherein said plurality of features include a feature with an aspect ratio greater than 40:1.

11. The method of claim 10, wherein said feature with an aspect ratio of at least 40:1 has a top critical dimension of 50 nanometers or less.

12. The method of claim 1, wherein said patterned mask includes a photoresist layer, an anti-reflective coating layer, and a hard mask layer;

13. The method of claim 1, wherein said dielectric layer includes alternating layers of silicon oxide and silicon nitride with a total thickness of at least 3 microns.

14. The method of claim 1, further comprising providing a chamber pressure, a power source, and a CO flow sufficient for said plasma to dissociate the CO and form a carbon species and an oxygen species, wherein the carbon species improves the mask etch selectivity of the patterned mask and the oxygen species prevents polymer necking and polymer clogging in the plurality of openings during etching.

15. The method of claim 1, wherein each opening has a profile, and wherein the CO and O2 are provided at flow rates sufficient to prevent polymer necking and polymer clogging in the plurality of openings and minimize distorting the profiles of the openings.

16. The method of claim 1, wherein the optional inert gas is argon.

17. The method of claim 1, wherein said dielectric layer includes a silicon nitride layer and said gas mixture includes a hydrofluorocarbon gas.

18. An etching method comprising:
providing a substrate into an etch chamber, said substrate having a patterned mask disposed on a dielectric layer, the patterned mask having a plurality of openings;
providing a gas mixture into the etch chamber, said gas mixture including CO, O₂, a fluorocarbon gas, and an optional inert gas, wherein the CO flow rate is between about 10% and 50% of the gas mixture flow rate, and wherein the CO and O₂ are provided at a ratio between about 3:1 and 6:1;
forming a plasma from the gas mixture; and,
etching in the presence of the plasma, a plurality of features in said dielectric layer through the plurality of openings, each feature having an aspect ratio and a sidewall profile, wherein at least one of said features has an aspect ratio greater than 40:1 and a roughly straight and undistorted sidewall profile.

19. The method of claim 18, further comprising increasing the CO flow rate as a percentage of the gas mixture flow rate during etching.

20. A machine-accessible storage medium having a set of machine-executable instructions stored thereon which, when executed by a data processing system, cause a system to perform a method comprising:
providing a substrate into an etch chamber, said substrate having a patterned mask disposed on a dielectric layer formed thereon, wherein the patterned mask has a plurality of openings;
providing a gas mixture into the etch chamber, said gas mixture including CO, O₂, a fluorocarbon gas, and an optional inert gas;
forming a plasma from the gas mixture; and,
etching in the presence of the plasma, a plurality of features in said dielectric layer through the plurality of openings, each feature having an aspect ratio, a top critical dimension, and a sidewall profile.

21. The method of claim 20, wherein the CO and O₂ are provided at a ratio between about 1:1 and 10:1.

22. The method of claim 20, wherein the CO flow rate is between about 10% and 50% of the gas mixture flow rate.

23. The method of claim 20, further comprising increasing the CO flow rate as a percentage of the gas mixture flow rate during etching.
